(19) United States
(12) Patent Application Publication
(10) Pub. No.: US 2025/0212532 A1
(43) Pub. Date: Jun. 26, 2025

(54) AVALANCHE INFRARED DETECTOR AND PREPARATION METHOD THEREOF

(71) Applicant: SHANGHAI INSTITUTE OF TECHNICAL PHYSICS, CAS, SHANGHAI (CN)

(72) Inventors: WEIDA HU, SHANGHAI (CN); HAILU WANG, SHANGHAI (CN); CHENYU HUANG, SHANGHAI (CN); HUI XIA, SHANGHAI (CN); WEI LU, SHANGHAI (CN)

(21) Appl. No.: 18/825,129

(22) Filed: Sep. 5, 2024

(30) Foreign Application Priority Data
Dec. 25, 2023 (CN) 202311785798.0

(51) Int. Cl. H01L 31/107; H01L 31/0216; H01L 31/0224; H01L 31/0352; H01L 31/103; H01L 31/18

(52) U.S. Cl. CPC H10F 30/225; H10F 30/221; H10F 71/00; H10F 77/148; H10F 77/206; H10F 77/306

(57) ABSTRACT

The present application relates to an avalanche infrared detector and a preparation method thereof. In the present application, a homogeneous structure is constructed based on an atomic layer number-dependent energy band structure of a two-dimensional van der Waals material, which can solve problems such as lattice mismatch and defects of the traditional heterojunction avalanche photodetectors and can inhibit the generation of main dark current components such as recombination current and tunneling current by detectors. A “peak” electric field at a stepwise homojunction interface is adopted to enhance a coulomb interaction between carriers, inhibit the hot carrier-phonon coupling, and reduce an energy loss caused by a relaxation process. The avalanche infrared detector provided by the present application can exhibit advantages such as high-speed response, high sensitivity, low avalanche threshold, and high gain under room-temperature working conditions, which expands an application range of the avalanche infrared detector.

### CROSS REFERENCE TO RELATED APPLICATION

This patent application claims the benefit and priority of Chinese Patent Application No. 202311785798.0, filed with the China National Intellectual Property Administration on Dec. 25, 2023, the disclosure of which is incorporated by reference herein in its entirety as part of the present application.

### TECHNICAL FIELD

The present disclosure belongs to the technical field of infrared detectors, and specifically relates to an avalanche infrared detector and a preparation method thereof.

### BACKGROUND

When the excess energy of photo-generated hot electrons is higher than the band gap of a material and the coulomb interaction between electrons is strong enough, these hot electrons can interact with electrons in valence bands to allow an energy exchange and thus excite additional electrons to enter conduction bands, which is called carrier multiplication. Obviously, the carrier multiplication allows the conversion and utilization of excess energy of hot carriers and reduces an energy loss caused by the relaxation process, thereby effectively improving the photogain. Therefore, the carrier multiplication can overcome the Shockley-Queisser limit of the photoelectric conversion efficiency.

Avalanche photodetectors are a class of typical devices based on hot carrier multiplication. Hot carriers undergo continuous collisional ionization under high reverse bias conditions to allow the multiplication of geometric progressions of photo-generated electrons and holes, such that a large photogain can be produced to allow highly-sensitive detection. Theoretically, the threshold energy required for the avalanche multiplication is approximately equal to the band gap (E_{g}) of a material, namely, the minimum energy required for the carrier to transition from a conduction band to a valence band. However, in the existing thin-film avalanche photodetectors, the multiplication efficiency of carriers is low and there is usually a high avalanche threshold energy (more than 22 times the band gap of a material), resulting in low photoelectric conversion efficiency. For example, threshold voltages of Si and InGaAs avalanche photodetectors exceed 120 V and 40 V, respectively. This is attributed to the following fact: in thin-film materials, the strict law of conservation of momentum restricts the redistribution of energy among carriers through Coulomb interactions (namely, the thermalization), and the strong electron-phonon coupling enhances the energy relaxation process of hot carriers. Therefore, avalanche photodetectors require a high working voltage to make carriers acquire sufficient kinetic energy to trigger an avalanche multiplication process, which causes the significant amplification of excess noise. In addition, thin-film PN junction avalanche photodetectors have technical problems such as lattice mismatch and defect and impurity diffusion caused by doping, and as a result, main dark current components such as SRH recombination current, diffusion current, and defect-assisted tunneling current significantly increase, which greatly limits the signal-to-noise ratio and sensitivity of a device.

### SUMMARY

An objective of the present disclosure is to provide an avalanche infrared detector and a preparation method thereof. The avalanche infrared detector provided by the present disclosure has characteristics such as high sensitivity, low avalanche threshold, high gain, and high photoelectric conversion efficiency.

To allow the above objective, the present disclosure provides the following technical solutions:

The present disclosure provides an avalanche infrared detector, including a substrate, a protective layer, and a homojunction layer that are stacked sequentially from bottom to top,
where a material of the homojunction layer is a two-dimensional van der Waals material;
the homojunction layer includes a thin-layer zone and a thick-layer zone; and
a source electrode is arranged on the thin-layer zone and a drain electrode is arranged on the thick-layer zone.

Preferably, the two-dimensional van der Waals material includes one or more selected from the group consisting of WSe₂, MoS₂, and MoTe₂.

Preferably, a thickness of the thin-layer zone is 2.1 nm to 5.6 nm; and
a thickness of the thick-layer zone is larger than 14 nm.

Preferably, the substrate is a silicon layer/silicon dioxide layer composite substrate.

Preferably, a material of a silicon layer is boron-doped P-type silicon; a thickness of the silicon layer is 500 μm to 525 μm; and
a thickness of a silicon dioxide layer is 285 nm to 300 nm.

Preferably, a material of the protective layer is aluminum oxide and/or hafnium dioxide.

Preferably, a thickness of the protective layer is 10 nm to 15 nm.

Preferably, the source electrode and the drain electrode each independently include a platinum layer and a gold layer that are stacked sequentially from bottom to top;
a thickness of the platinum layer is 15 nm to 35 nm; and
a thickness of the gold layer is 70 nm to 100 nm.

The present disclosure further provides a preparation method of the avalanche infrared detector described in the above technical solution, including the following steps:
preparing the protective layer and the homojunction layer sequentially on a surface of the substrate; and
fabricating the source electrode on the thin-layer zone of the homojunction layer, and fabricating the drain electrode on the thick-layer zone of the homojunction layer, so as to obtain the avalanche infrared detector.

Preferably, the homojunction layer is prepared by a transfer process or an etching process,
where the transfer process includes: preparing the homojunction layer through mechanical exfoliation, and transferring the homojunction layer to a surface of the protective layer through polydimethylsiloxane-assisted physical transfer; and
the etching process includes: preparing a two-dimensional van der Waals material layer with a uniform thickness through the mechanical exfoliation, transferring the two-dimensional van der Waals material layer with the uniform thickness to the surface of the protective layer through the polydimethylsiloxane-assisted physical transfer, and thinning the two-dimensional van der Waals material layer with the uniform thickness through reactive ion etching method to obtain the homojunction layer.

The present disclosure provides an avalanche infrared detector, including a substrate, a protective layer, and a homojunction layer that are stacked sequentially from bottom to top, where a material of the homojunction layer is a two-dimensional van der Waals material; the homojunction layer includes a thin-layer zone and a thick-layer zone; and a source electrode is arranged on the thin-layer zone and a drain electrode is arranged on the thick-layer zone. In the present disclosure, a homogeneous structure is constructed based on an atomic layer number-dependent energy band structure of a two-dimensional van der Waals material, which can solve problems such as lattice mismatch and defects of the traditional heterojunction avalanche photodetectors and can inhibit the generation of main dark current components such as recombination current and tunneling current by detectors. A “peak” electric field at a stepwise homojunction interface is adopted to enhance a coulomb interaction between carriers, inhibit the hot carrier-phonon coupling, and reduce an energy loss caused by a relaxation process. The avalanche infrared detector provided by the present disclosure can exhibit advantages such as high-speed response, high sensitivity, low avalanche threshold, and high gain under room-temperature working conditions, which expands an application range of the avalanche infrared detector.

### BRIEF DESCRIPTION OF THE DRAWINGS

FIG. 1 is a schematic structural diagram of the avalanche infrared detector provided by the present disclosure, where 1-substrate, 2-protective layer, 3-homojunction layer, 4-source electrode, and 5-drain electrode;

FIG. 2 is a schematic diagram of a cross section of the homojunction layer provided by the present disclosure;

FIGS. 3A-3B show a transmission electron microscopy image at a junction between a thin-layer zone and a thick-layer zone of the homojunction layer in Example 1 and corresponding Raman spectra;

FIG. 4 shows I-V characteristic curves of the avalanche infrared detector obtained in Example 1 in the dark and under light;

FIG. 5 shows multiplication factors (or photogain) of the avalanche infrared detector obtained in Example 1 in the dark and under light;

FIG. 6 shows I-V characteristic curves of the avalanche infrared detector obtained in Example 1 with a temperature change;

FIG. 7 shows a time-resolved photoresponse curve of the avalanche infrared detector obtained in Example 1; and

FIGS. 8A-8B show the imaging of SITP letter graphics by the avalanche infrared detector obtained in Example 1.

### DETAILED DESCRIPTION OF THE EMBODIMENTS

The present disclosure provides an avalanche infrared detector, including a substrate, a protective layer, and a homojunction layer that are stacked sequentially from bottom to top.

A material of the homojunction layer is a two-dimensional van der Waals material.

The homojunction layer includes a thin-layer zone and a thick-layer zone.

A source electrode is arranged on the thin-layer zone and a drain electrode is arranged on the thick-layer zone.

In the present disclosure, unless otherwise specified, all materials are commercially-available products well known to those skilled in the art.

In the present disclosure, the substrate is preferably a silicon layer/silicon dioxide layer composite substrate. In the present disclosure, a material of a silicon layer is preferably boron-doped P-type silicon, an electrical resistivity of the boron-doped P-type silicon is preferably 0.05 Ω·cm, and a thickness of the silicon layer is preferably 500 μm to 525 μm. In the present disclosure, a thickness of a silicon dioxide layer is preferably 285 nm to 300 nm.

In the present disclosure, a material of the protective layer is preferably aluminum oxide and/or hafnium dioxide. In the present disclosure, a thickness of the protective layer is preferably 10 nm to 15 nm. In the present disclosure, the protective layer can reduce the harmful scattering of the substrate to the two-dimensional van der Waals material.

In the present disclosure, the two-dimensional van der Waals material preferably includes one or more selected from the group consisting of WSe₂, MoS₂, and MoTe₂. In the present disclosure, a thickness of the thin-layer zone is preferably 2.1 nm to 5.6 nm (namely, 3 to 8 atomic layers), and a thickness of the thick-layer zone is preferably greater than 14 nm (namely, more than 20 atomic layers). The present disclosure does not have a special restriction on areas of the thin-layer zone and the thick-layer zone, and areas well known to those skilled in the art may be adopted. In the present disclosure, the atomic-level (3 Å to 4 Å) thickness of the two-dimensional van der Waals material leads to a strong quantum size effect, which significantly enhances the coulomb interaction. Therefore, the atomic-level thickness is very conducive to the implementation of an energy exchange between carriers and a multiplication process. In addition, van der Waals materials have much higher exciton binding energy (hundreds of meV) than bulk materials and a low electron-phonon coupling efficiency, and thus can allow a long carrier lifetime, which is conducive to reducing an energy loss caused by a relaxation process. Because there is no dangling bond on a surface of the van der Waals material, a drain current on the surface is inhibited. Due to the atomic-level thickness, an intrinsic carrier concentration of the van der Waals material is easily regulated by a local field, and a volume-associated diffusion current can be significantly reduced.

In the present disclosure, the source electrode and the drain electrode each preferably independently include a platinum layer and a gold layer that are stacked sequentially from bottom to top, a thickness of the platinum layer is preferably 15 nm to 35 nm, and a thickness of the gold layer is preferably 70 nm to 100 nm. In the present disclosure, an area of the source electrode is preferably smaller than an area of the thin-layer zone, and an area of the drain electrode is preferably smaller than an area of the thick-layer zone.

The present disclosure further provides a preparation method of the avalanche infrared detector described in the above technical solution, including the following steps:
the protective layer and the homojunction layer are prepared sequentially on a surface of the substrate; and
the source electrode is fabricated on the thin-layer zone of the homojunction layer, and the drain electrode is fabricated on the thick-layer zone of the homojunction layer, so as to obtain the avalanche infrared detector.

In the present disclosure, the protective layer and the homojunction layer are prepared sequentially on a surface of the substrate.

In the present disclosure, the protective layer is prepared preferably through atomic layer deposition. The present disclosure does not have a special restriction on a process of the atomic layer deposition, and a process well known to those skilled in the art may be adopted.

In the present disclosure, when the material of the protective layer is aluminum oxide, the preparation of the protective layer includes the following step: with trimethylaluminum as a precursor, the surface of the substrate is subjected to atomic layer deposition. The atomic layer deposition is conducted preferably at 150° C., and the atomic layer deposition is conducted preferably in a nitrogen atmosphere.

In the present disclosure, the homojunction layer is prepared preferably by a transfer process or an etching process.

In the present disclosure, the transfer process preferably includes: the homojunction layer is prepared through mechanical exfoliation, and then transferred to the surface of the protective layer through polydimethylsiloxane-assisted physical transfer. The present disclosure does not have a special restriction on a process of the mechanical exfoliation, and a process well known to those skilled in the art may be adopted.

In the present disclosure, the etching process preferably includes: a two-dimensional van der Waals material layer with a uniform thickness is prepared through the mechanical exfoliation, then transferred to the surface of the protective layer through the polydimethylsiloxane-assisted physical transfer, and thinned through reactive ion etching method to obtain the homojunction layer. The present disclosure does not have a special restriction on processes of the mechanical exfoliation and the reactive ion etching, and processes well known to those skilled in the art may be adopted.

In the present disclosure, the source electrode is fabricated on the thin-layer zone of the homojunction layer.

The present disclosure does not have a special restriction on a fabrication method of the source electrode, and a fabrication method well known to those skilled in the art may be adopted.

In a specific embodiment of the present disclosure, the fabrication of the source electrode preferably includes: a source electrode pattern is formed in the thin-layer zone through photolithography, a platinum layer and a gold layer are deposited sequentially on the source electrode pattern through metal deposition, and lift-off process is conducted to obtain the source electrode. The present disclosure does not have a special restriction on processes of the photolithography and the metal deposition, and processes well known to those skilled in the art may be adopted. In the present disclosure, a deposition rate of the metal deposition is preferably 0.1 Å/s to 0.5 Å/s.

In the present disclosure, the drain electrode is fabricated on the thick-layer zone of the homojunction layer, so as to obtain the avalanche infrared detector.

In the present disclosure, a fabrication method of the drain electrode is consistent with the fabrication method of the source electrode, and is not repeated here.

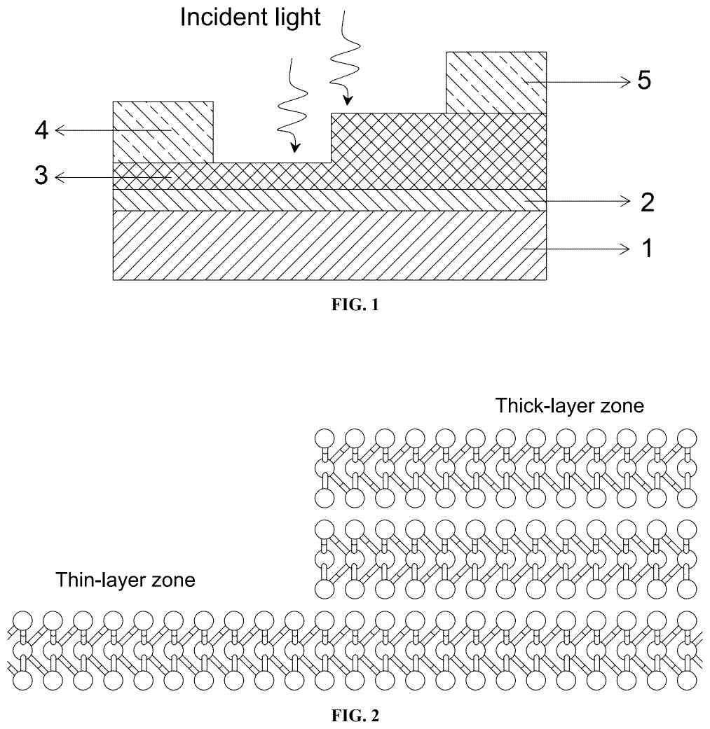

A schematic structural diagram of the avalanche infrared detector provided by the present disclosure is shown in FIG. 1, where 1 represents a substrate, 2 represents a protective layer, 3 represents a homojunction layer, 4 represents a source electrode, and 5 represents a drain electrode.

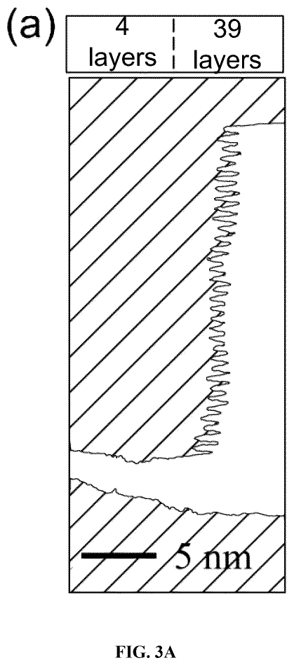

In the present disclosure, a schematic diagram of a cross section of the homojunction layer is shown in FIG. 2.

In order to further illustrate the present disclosure, the avalanche infrared detector and the preparation method thereof provided by the present disclosure are described in detail below with reference to the accompanying drawings and examples, but the accompanying drawings and the examples should not be construed as limiting the protection scope of the present disclosure.

### EXAMPLE 1

A silicon layer/silicon dioxide layer composite substrate was adopted, in which a material of a silicon layer was boron-doped P-type silicon with an electrical resistivity of 0.05 Ω·cm and a thickness of 525 μm, and a thickness of a silicon dioxide layer was 285 nm.

An aluminum oxide protective layer with a thickness of 15 nm was allowed to grow on a surface of the silicon layer/silicon dioxide layer composite substrate through atomic layer deposition. The atomic layer deposition was conducted at a growth temperature of 150° C. with trimethylaluminum as a precursor and high-purity nitrogen as a purge gas.

A WSe₂ homojunction layer (in which a thickness of a thin-layer zone was 2.8 nm and a thickness of a thick-layer zone was 27.3 nm) was prepared through mechanical exfoliation and then transferred to a surface of the aluminum oxide protective layer through polydimethylsiloxane-assisted physical transfer.

A source electrode pattern was formed in the thin-layer zone through photolithography, a platinum layer and a gold layer were deposited sequentially on the source electrode pattern through metal deposition (deposition rate: 0.1 Å/s), and lift-off process was conducted to obtain the source electrode. A thickness of the platinum layer was 25 nm and a thickness of the gold layer was 80 nm.

A drain electrode pattern was formed in the thick-layer zone through photolithography, a platinum layer and a gold layer were deposited sequentially on the drain electrode pattern through metal deposition (deposition rate: 0.1 Å/s), and lift-off process was conducted to obtain the drain electrode, so as to obtain the avalanche infrared detector. A thickness of the platinum layer was 25 nm and a thickness of the gold layer was 80 nm.

### EXAMPLE 2

A silicon layer/silicon dioxide layer composite substrate was adopted, in which a material of a silicon layer was boron-doped P-type silicon with an electrical resistivity of 0.05 Ω·cm and a thickness of 525 μm, and a thickness of a silicon dioxide layer was 300 nm.

An aluminum oxide protective layer with a thickness of 10 nm was allowed to grow on a surface of the silicon layer/silicon dioxide layer composite substrate through atomic layer deposition. The atomic layer deposition was conducted at a growth temperature of 150° C. with trimethylaluminum as a precursor and high-purity nitrogen as a purge gas.

A WSe₂ material layer with a uniform thickness was prepared through mechanical exfoliation and then transferred to a surface of the aluminum oxide protective layer through polydimethylsiloxane-assisted physical transfer, and a side of the WSe₂ material layer with the uniform thickness was thinned through reactive ion etching method to obtain a homojunction layer (in which a thickness of a thin-layer zone was 4.2 nm and a thickness of a thick-layer zone was 14.7 nm).

A source electrode pattern was formed in the thin-layer zone through photolithography, a platinum layer and a gold layer were deposited sequentially on the source electrode pattern through metal deposition (deposition rate: 0.2 Å/s), and lift-off process was conducted to obtain the source electrode. A thickness of the platinum layer was 35 nm and a thickness of the gold layer was 100 nm.

A drain electrode pattern was formed in the thick-layer zone through photolithography, a platinum layer and a gold layer were deposited sequentially on the drain electrode pattern through metal deposition (deposition rate: 0.2 Å/s), and lift-off process was conducted to obtain the drain electrode, so as to obtain the avalanche infrared detector. A thickness of the platinum layer was 35 nm and a thickness of the gold layer was 100 nm.

### PERFORMANCE TESTING

### Test Example 1

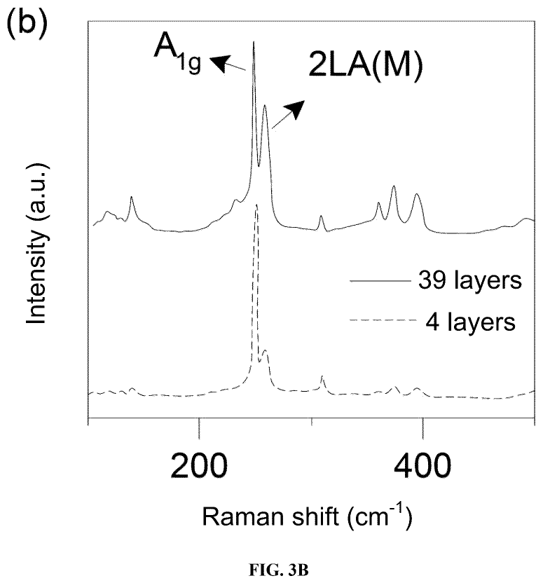

FIGS. 3A-3B show a transmission electron microscopy image at a junction between a thin-layer zone and a thick-layer zone of the homojunction layer in Example 1 and corresponding Raman spectra.

It can be seen from FIGS. 3A-3B that 4 and 39 atomic layers can be clearly observed in semiconductor WSe₂ materials at two sides of the homojunction interface under a high-magnification transmission electron microscope, and in the Raman spectra of the WSe₂ materials (excitation light source: 532 nm), characteristic peaks at 138.8 cm⁻¹, 249.3 cm⁻¹ (corresponding to the A_{1g} phonon mode), 257.5 cm⁻¹ (corresponding to the 2LA (M) phonon mode), 309.5 cm⁻¹, 360.0 cm⁻¹, 373.1 cm⁻¹, and 395.7 cm⁻¹ can be clearly observed. Compared with the 39-layer WSe₂ material, 2LA (M) of the 4-layer WSe₂ material is significantly reduced, which partly indicates that the electron-phonon interaction in the material weakens with the decrease in the atomic layer number.

### Test Example 2

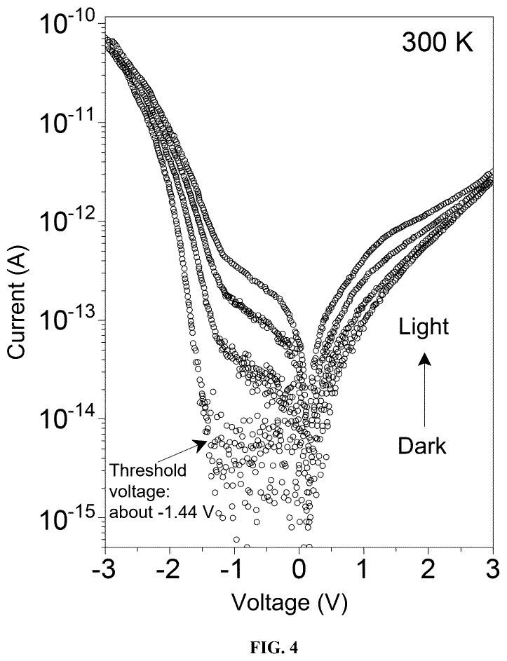

FIG. 4 shows I-V characteristic curves of the avalanche infrared detector obtained in Example 1 in the dark and under light. Test conditions are as follows: incident light with a wavelength of 520 nm is adopted, a working temperature is the room temperature of 300 K, and a bias is externally applied to a drain electrode, namely, the thick-layer WSe₂ zone.

It can be seen from FIG. 4 that the I-V characteristic curve in the dark can be divided into a rectification region (voltage: −1.44 V to 3 V) and a multiplication region (voltage: −3 V to −1.44 V). In the rectification region, a cut-off current drops to 10 fA, and after a threshold voltage (−1.44 V) is exceeded, a current increases at a rate of 400 mV/dec. At incident light powers of 2.5 nW, 9.9 nW, and 25 nW, the device can exhibit a distinct photoresponse.

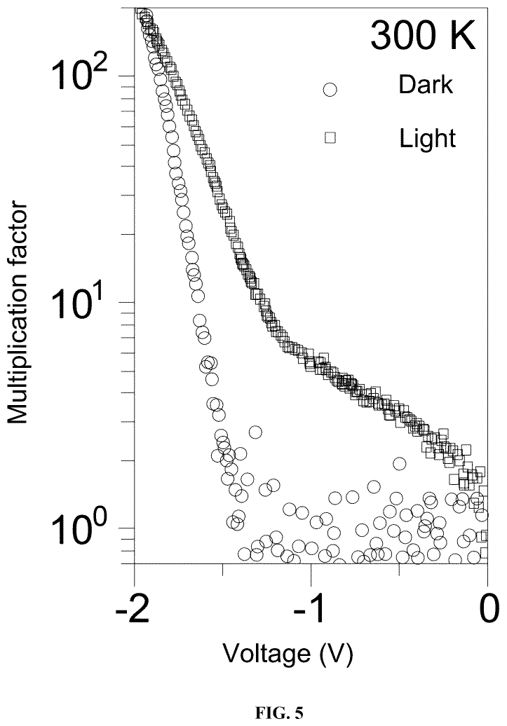

FIG. 5 shows multiplication factors of the avalanche infrared detector obtained in Example 1 in the dark and under light. It can be seen from FIG. 5 that, at the room temperature of 300 K and an incident light wavelength of 520 nm, a multiplication factor can reach 10².

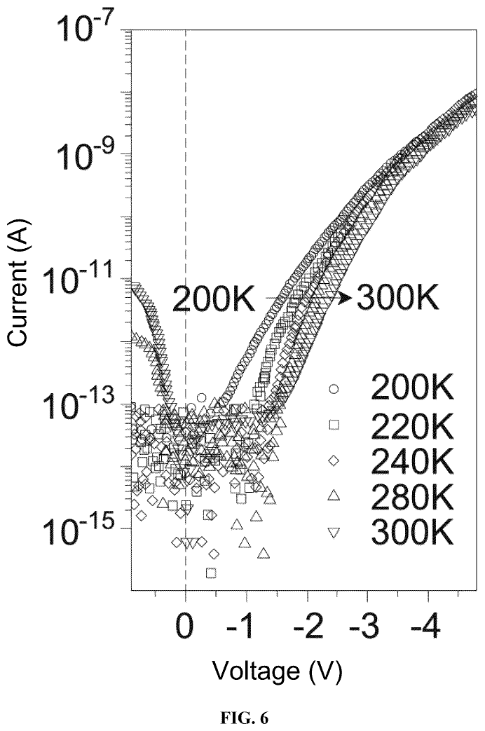

FIG. 6 shows an I-V characteristic curve of the avalanche infrared detector obtained in Example 1 with a temperature change. It can be seen from FIG. 6 that, when a temperature increases from 200 K to 300 K, the threshold voltage gradually increases, that is, it exhibits a significant positive temperature coefficient.

FIG. 7 shows a time-resolved photoresponse curve of the avalanche infrared detector obtained in Example 1. It can be seen from FIG. 7 that, at room temperature, an externally-applied bias of −3 V, and an incident light wavelength of 830 nm, the rise and fall times of the device are 10 μs and 9 μs, respectively.

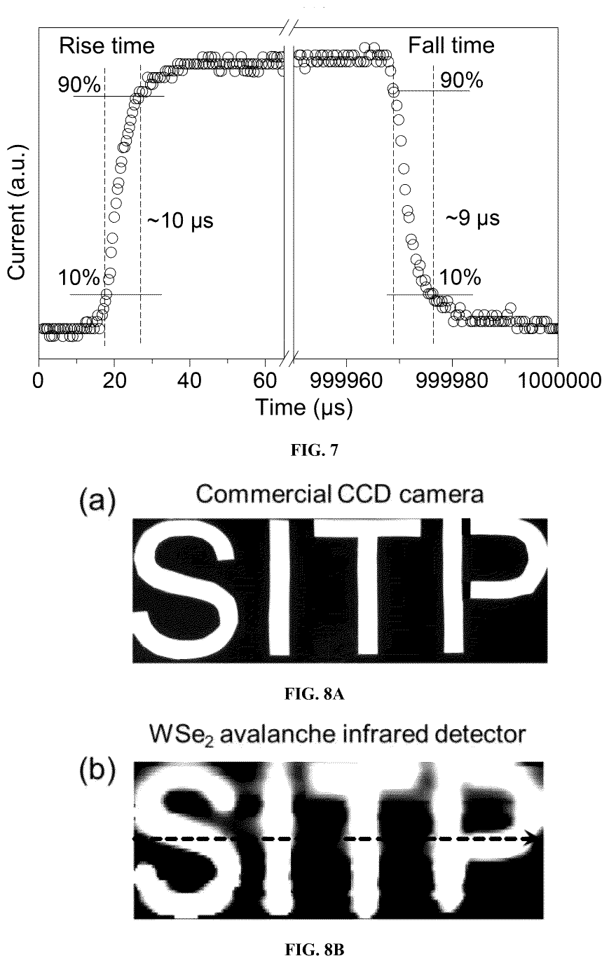

FIGS. 8A-8B show the imaging of a SITP letter graphics by the avalanche infrared detector obtained in Example 1. It can be seen from FIGS. 8A-8B that, at room temperature and an externally-applied bias of −2 V, the device images the letters “SITP”.

Although the present disclosure is described in detail in the above examples, these examples are merely some rather than all of the examples of the present disclosure. Other examples can be obtained based on these examples without creative efforts, and all of these examples shall fall within the protection scope of the present disclosure.

What is claimed is:

1. An avalanche infrared detector, comprising a substrate, a protective layer, and a homojunction layer that are stacked sequentially from bottom to top,
wherein a material of the homojunction layer is a two-dimensional van der Waals material;
the homojunction layer comprises a thin-layer zone and a thick-layer zone; and
a source electrode is arranged on the thin-layer zone and a drain electrode is arranged on the thick-layer zone.

2. The avalanche infrared detector according to claim 1, wherein the two-dimensional van der Waals material comprises at least one material selected from the group consisting of WSe₂, MoS₂, and MoTe₂.

3. The avalanche infrared detector according to claim 2, wherein a thickness of the thin-layer zone is 2.1 nm to 5.6 nm; and
a thickness of the thick-layer zone is larger than 14 nm.

4. The avalanche infrared detector according to claim 1, wherein a thickness of the thin-layer zone is 2.1 nm to 5.6 nm; and
a thickness of the thick-layer zone is larger than 14 nm.

5. The avalanche infrared detector according to claim 1, wherein the substrate is a silicon layer/silicon dioxide layer composite substrate.

6. The avalanche infrared detector according to claim 5, wherein a material of a silicon layer is boron-doped P-type silicon; a thickness of the silicon layer is 500 μm to 525 μm; and
a thickness of a silicon dioxide layer is 285 nm to 300 nm.

7. The avalanche infrared detector according to claim 1, wherein a material of the protective layer is at least one material selected from the group consisting of aluminum oxide and hafnium dioxide.

8. The avalanche infrared detector according to claim 7, wherein a thickness of the protective layer is 10 nm to 15 nm.

9. The avalanche infrared detector according to claim 1, wherein a thickness of the protective layer is 10 nm to 15 nm.

10. The avalanche infrared detector according to claim 1, wherein each of the source electrode and the drain electrode comprises a platinum layer and a gold layer that are stacked sequentially from bottom to top;
wherein a thickness of the platinum layer is 15 nm to 35 nm; and
wherein a thickness of the gold layer is 70 nm to 100 nm.

11. A preparation method of the avalanche infrared detector according to claim 1, the preparation method comprising the steps of:
preparing the protective layer and the homojunction layer sequentially on a surface of the substrate; and
fabricating the source electrode on the thin-layer zone of the homojunction layer, and fabricating the drain electrode on the thick-layer zone of the homojunction layer.

12. The preparation method according to claim 11, wherein the step of preparing the homojunction layer comprises a transfer process or an etching process,
wherein the transfer process comprises: preparing the homojunction layer through mechanical exfoliation, and transferring the homojunction layer to a surface of the protective layer through polydimethylsiloxane-assisted physical transfer; and
wherein the etching process comprises: preparing a two-dimensional van der Waals material layer with a uniform thickness through the mechanical exfoliation, transferring the two-dimensional van der Waals material layer with the uniform thickness to the surface of the protective layer through the polydimethylsiloxane-assisted physical transfer, and thinning the two-dimensional van der Waals material layer with the uniform thickness through reactive ion etching method to obtain the homojunction layer.

13. The preparation method according to claim 11, wherein the two-dimensional van der Waals material comprises at least one material selected from the group consisting of WSe₂, MoS₂, and MoTe₂.

14. The preparation method according to claim 11, wherein a thickness of the thin-layer zone is 2.1 nm to 5.6 nm; and
a thickness of the thick-layer zone is larger than 14 nm.

15. The preparation method according to claim 11, wherein the substrate is a silicon layer/silicon dioxide layer composite substrate.

16. The preparation method according to claim 15, wherein a material of the silicon layer is boron-doped P-type silicon; a thickness of the silicon layer is 500 μm to 525 μm; and
a thickness of the silicon dioxide layer is 285 nm to 300 nm.

17. The preparation method according to claim 11, wherein a material of the protective layer is at least one material selected from the group consisting of aluminum oxide and/or hafnium dioxide.

18. The preparation method according to claim 11, wherein a thickness of the protective layer is 10 nm to 15 nm.

19. The preparation method according to claim 11, wherein each of the source electrode and the drain electrode comprises a platinum layer and a gold layer that are stacked sequentially from bottom to top;
wherein a thickness of the platinum layer is 15 nm to 35 nm; and
wherein a thickness of the gold layer is 70 nm to 100 nm.
